(19) United States
(12) Patent Application Publication
(10) Pub. No.: US 2022/0007531 A1
(43) Pub. Date: Jan. 6, 2022

(54) COVERS FOR ELECTRONIC DEVICES

(71) Applicant: Hewlett-Packard Development Company, L.P., Spring, TX (US)

(72) Inventors: Lien-Chia Chiu, Taipei City (TW); Ya-Ting Yeh, Taipei City (TW); Kuan-Ting Wu, Taipei City (TW)

(73) Assignee: Hewlett-Packard Development Company, L.P., Spring, TX (US)

(21) Appl. No.: 17/298,648

(22) PCT Filed: Jul. 25, 2019
(86) PCT No.: PCT/US2019/043423

§ 371 Date: May 31, 2021

(51) Int. Cl. H05K 5/03; B32B 15/08; B32B 3/02; C25D 11/02; C25D 11/30; C23C 14/16; C23C 14/20; C23C 14/24; C23C 28/00; B05D 3/12; B05D 1/02; B05D 5/06; B05D 7/00

(52) U.S. Cl. CPC H05K 5/03; B32B 2457/00; B32B 3/02; C25D 11/026; C25D 11/30; C23C 14/16; C23C 14/20; C23C 14/24; C23C 28/322; C23C 28/345; B05D 3/12; B05D 1/02; B05D 5/06; B05D 7/53; B32B 2250/02; B32B 2255/06; B32B 2255/10; B32B 2255/205; B32B 2255/26; B32B 2255/28; B32B 15/08

(57) ABSTRACT

The present disclosure is drawn to covers for electronic devices. In one example, a cover for an electronic device can include an enclosure with a light metal substrate joined with an insert molding plastic part, and a protective treatment layer on the light metal substrate and the insert molding plastic part. A transparent primer coating on the protective treatment layer, and a paint coating on the transparent primer coating. A milled edge along the insert molding plastic part, wherein the milled edge cuts through the paint coating to expose the transparent primer coating.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market. Devices such as mobile phones, tablets and portable computers are generally provided with a casing. The casing typically provides a number of functional features, e.g. protecting the device from damage.

### BRIEF DESCRIPTION OF THE DRAWING

FIGS. 1A-1B are cross-sectional views illustrating an example cover for an electronic device in accordance with examples of the present disclosure;

FIG. 2 is a cross-sectional view illustrating another example cover for an electronic device in accordance with examples of the present disclosure;

FIG. 3 is a top down view and a partial cross-sectional view of an example cover for an electronic device in accordance with the present disclosure;

FIG. 4 is a cross-sectional view of an example electronic device in accordance with the present disclosure;

FIG. 5 is a flowchart illustrating an example method of making a cover for an electronic device in accordance with the present disclosure; and

FIGS. 6A-6G are cross-sectional views showing another example method of making a cover for an electronic device in accordance with the present disclosure.

### DETAILED DESCRIPTION

The present disclosure describes covers for electronic devices. In one example, a cover for an electronic device includes an enclosure with a light metal substrate joined with an insert molding plastic part. The light metal substrate may be milled, stamped, forged, or otherwise altered to create feature to accept the insert molding plastic part. The cover also includes a protective treatment layer covering the light metal substrate and the insert molding plastic part, a transparent primer coating covering the protective treatment layer, and a paint coating on the transparent primer coating. A milled edge is present along the insert molding plastic part, wherein the milled edge cuts through the paint coating to expose the transparent primer coating. The milled edge can be referred to as a chamfered edge. A second protective treatment layer can be positioned between the protective treatment layer and the light metal substrate. The second protective treatment layer can be a micro-arc oxidation layer or a passivation layer. In one example, the light metal substrate can be a magnesium alloy. The protective treatment layer can be formed using physical vapor deposition (PVD) or non-conductive vacuum metalizing (NCVM). The transparent primer coating is transparent to allow the insert molding plastic part to be visible. The paint coating can be a multilayered coating including one or both of a base coat or a top coat. The base coat if present can include a polyester, a polyurethane, or a copolymer thereof. The top coat if present can be clear and can include a polyurethane, a polyacrylic or polyacrylate, a urethane, an epoxy, or a copolymer thereof. The milled edge can be formed using CNC mill or laser engraving. The cover can further include a second milled edge along a second insert molding plastic part. The milled edge allows the insert molding plastic part to be visible through the transparent primer coating and the protective treatment layer.

In another example, an electronic device can include an electronic component and a cover enclosing the electronic component. The cover can include an enclosure including a light metal substrate joined with an insert molding plastic part, a protective treatment layer on the light metal substrate and the insert molding plastic part, a transparent primer coating on the protective treatment layer, a paint coating on the transparent primer coating, and a milled edge along the insert molding plastic part, where the milled edge cuts through the paint coating to expose the transparent primer coating. The electronic device can be a laptop housing, a desktop housing, a keyboard housing, a mouse housing, a printer housing, a smartphone housing, a tablet housing, a monitor housing, a television screen housing, a speaker housing, a game console housing, a video player housing, an audio player housing, or a combination thereof. The milled edge can be located at an edge of a touchpad, an edge of a fingerprint scanner, or an edge of a logo. The cover can further include multiple milled edges with multiple colors at different milled edges.

In another example, a method of making a cover for an electronic device includes, for example, forming an enclosure with a light metal substrate, joining the light metal substrate with an insert molding plastic part. The method can further include applying a first protective treatment layer on the light metal substrate and the insert molding plastic part, applying a transparent primer coating on the protective treatment layer, and applying a paint coating on the transparent primer coating. The method can further include milling an edge along the insert molding plastic part to cut through the paint coating and to expose the transparent primer coating.

It is noted that when discussing the cover, the electronic device, or the method of manufacturing the cover, such discussions of one example are to be considered applicable to the other examples, whether or not they are explicitly discussed in the context of that example. Thus, in discussing a metal alloy in the context of the cover, such disclosure is also relevant to and directly supported in the context of the electronic device, the method of manufacturing the multi-color electronic housing, and vice versa.

### Covers for Electronic Devices

The present disclosure describes covers for electronic devices that can be strong and lightweight and have a decorative appearance. The cover can provide an enclosure for an electronic device and the enclosure can include a light metal substrate. The term “light metal” refers to metals and alloys that are generally any metal of relatively low density including metal that is less than about 5 g/cm³ in density. In some cases, light metal can be a material including aluminum, magnesium, titanium, lithium, niobium, zinc, and alloys thereof. These light metals can have useful properties, such as low weight, high strength, and an appealing appearance. However, some of these metals can be easily oxidized at the surface, and may be vulnerable to corrosion or other chemical reactions at the surface. For example, magnesium or magnesium alloys in particular can be used to form covers for electronic devices because of the low weight and high strength of magnesium. Magnesium can have a somewhat porous surface that can be vulnerable to chemical reactions and corrosion at the surface. In some examples, magnesium or magnesium alloy can be treated by micro-arc oxidation to form a layer of protective oxide at the surface. With this example in mind, it is understood that magnesium alloy may be described herein as a class of alloys in some detail by way of example for convenience, but it is also understood that other light metal substrates can be freely substituted for the magnesium alloy examples herein with respect to the covers, electronic devices, and methods herein.

Using magnesium or magnesium alloy as an example class of metal substrates that can be used, this material can form a protective oxide layer that can increase the chemical resistance, hardness, and durability of the magnesium or magnesium alloy. However, micro-arc oxidation can also create a dull appearance instead of the original luster of the metal. In other examples, as an alternative to the MAO the magnesium or magnesium alloy can be treated using a passivation layer. The passivation layer may contain at least one of molybdates, vanadates, phosphates, chromates, stannates and manganese salts.

The present disclosure describes covers for electronic devices that can utilize the above metals for their favorable properties and at the same time the metals can be protected from corrosion. Furthermore, the covers can have an attractive appearance. In some cases, it can be desirable to chamfer certain edges of the cover for ergonomics and/or to enhance the appearance of the cover. Some examples of edges that may be chamfered can include an edge surrounding a track pad on a lap top, an edge surrounding a fingerprint scanner, an outer edge of a smartphone housing, and so on. The covers described herein can include a chamfered edge that can have a customized appearance such as a metallic luster appearance, a colored metallic luster appearance, or an opaque colored appearance.

In certain examples, the cover can have a first protective coating such as a MAO layer or a passivation layer and a second protective coating or treatment layer such as a PVD or NCVM coating. The cover can additionally be protected by a third layer of transparent primer coating and a fourth protective paint coating which may comprise multiple layer of paint. The milled edge can cut through the fourth protective layer, meaning the paint coating, to expose the transparent primer coating below. The milled edge may also cut through a portion of the transparent primer coating. The milled edge may be referred to as a chamfer or a chamfered edge and may be accomplished using computer numeric control (CNC) or laser engraving. The paint coating may include more than one layer. For example, the paint coating may include one, two, three, or four layers. The paint coating may include a base coat and a top coat. The base coat may include a polyester, a polyurethane, or a copolymer thereof. The top coat may be clear or transparent and may include a polyurethane, a polyacrylic or polyacrylate, a urethane, an epoxy, or a copolymer thereof.

The passivation layer for the first protective coating may be opaque and may include molybdates, vanadates, phosphates, chromates, stannates, manganese salts, or a combination thereof. The passivation layer may be 1-5 μm thick. The second protective treatment layer may be a PVD or NCVM coating. The PVD or NCVM coating may be composed of titanium, chromium, nickel, zinc, zirconium, manganese, copper, aluminum, tin, molybdenum, tantalum, tungsten, hafnium, gold, vanadium, silver, platinum, graphite, and alloy combinations thereof. The second protective treatment layer may be 30-100 nm thick.

In various examples, resultant protection can be transparent, semi-transparent, or opaque. Different colors may be used at different edges of the cover. The different colors may be introduced by employing different colorants, such as dyes or pigments, in the insert molding plastic parts in one area of the enclosure as compared to another. Thus, the milled edge can have a natural metallic luster appearance, a colored metallic appearance, or an opaque colored appearance depending on the type of material used for the insert molding plastic parts and the transparent primer coating. The color of the milled edge can be customized and in some cases the color of the milled edge can be selected to contrast with or compliment the color of the protective coating on the cover substrate.

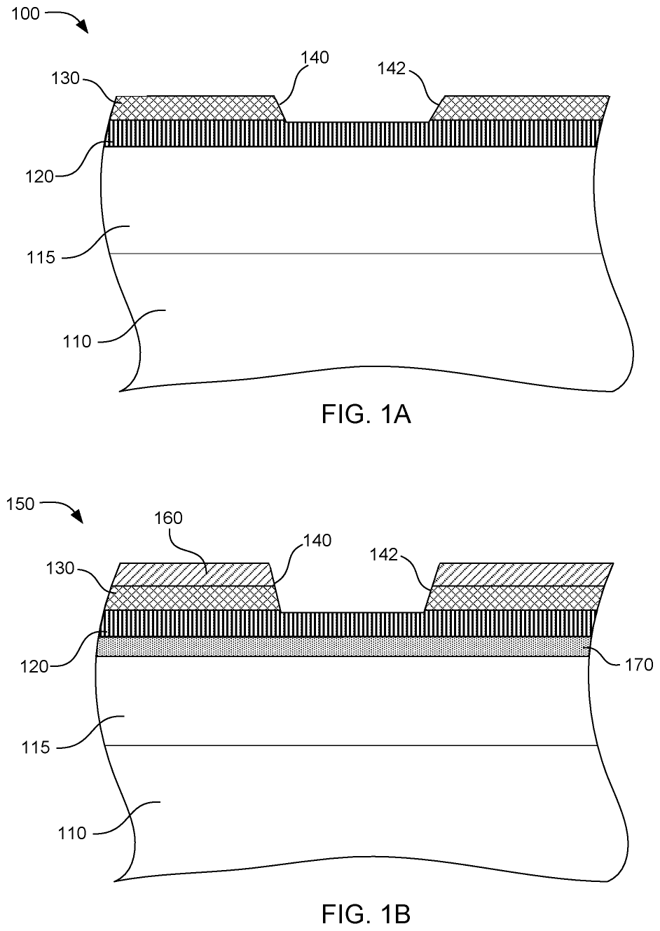

FIG. 1A shows an example cover 100 for an electronic device. The cover 100 includes a light metal substrate 110 joined with an insert molding plastic part 115. The light metal substrate 110 may be forged, stamped, or CNC milled to create a feature or structure to be joined with the insert molding plastic part 115. The insert molding plastic part 115 in this example is covered with a transparent primer coating 120. The transparent primer coating 120 in this example is covered with a first paint coating 130. An edge 140, 142 can then be milled to create a milled edge or a chamfer whereby the chamfer cuts through the first paint coating 130 to expose the transparent primer coating.

As shown in FIG. 1A, in this example the edge 140, 142 of the first paint coating 130 can be chamfered by cutting away material to create an opening in the first paint coating 130. The term “chamfered” or “chamfered edge” may refer specifically to the sloped face created by the chamfering or milling. In many cases, the original edge can be a 90° angle edge, and the chamfer can create a sloping face at a 45° angle. However, in some examples the original edge can have a different angle and the chamfer can create a sloping surface with a different angle. The milled edge can be performed using CNC techniques or laser engraving. In further examples, a milled edge can be performed using a milling machine with a cutting bit oriented to cut away the edge and create the sloped surface of the milled edge. In other examples, the milled edge can be performed by laser cutting, water jet cutting, sanding, or any other suitable method.

As mentioned above, the transparent primer coating 120 can be transparent or clear such that the insert molding plastic part 115 is visible through the transparent primer coating 120. The term “transparent” is a flexible term that allows for some amount of light absorption, provided the layer can still provide visibility through the transparent primer coating, e.g., from 80% to 100% transparent at the thickness applied is considered to be transparent herein.

FIG. 1B shows an example cover 150 for an electronic device. The cover 150 includes a light metal substrate 110 joined with an insert molding plastic part 115. The light metal substrate 110 may be forged, stamped, or CNC milled to create a feature or structure to be joined with the insert molding plastic part 115. The insert molding plastic part 115 can be covered with a transparent primer coating 120. The transparent primer coating 120 can be covered with a protective treatment layer 170. The protective treatment layer 170 can be deposited using PVD or NCVM. The protective treatment layer 170 may be composed of titanium, chromium, nickel, zinc, zirconium, manganese, copper, aluminum, tin, molybdenum, tantalum, tungsten, hafnium, gold, vanadium, silver, platinum, graphite, and alloy combinations thereof. Before the protective treatment layer 170 is deposited, the insert molding plastic part 115 and the light metal substrate 110 may be coated with a protective coating, not pictured, that may be a micro-arc oxidation layer or a passivation layer.

The transparent primer coating can be covered with a first paint coating 130. The first paint coating 130 can be covered with a second paint coating 160. The first paint coating 130 may be a base coat and the second paint coating 160 may be a clear top coat. It should be appreciated that the transparent primer coating 120 can be covered any number of paint coatings. An edge 140, 142 can be milled to create a milled edge or a chamfer whereby the chamfer cuts through the first paint coating 130 and the second paint coating 160 to expose the transparent primer coating 120.

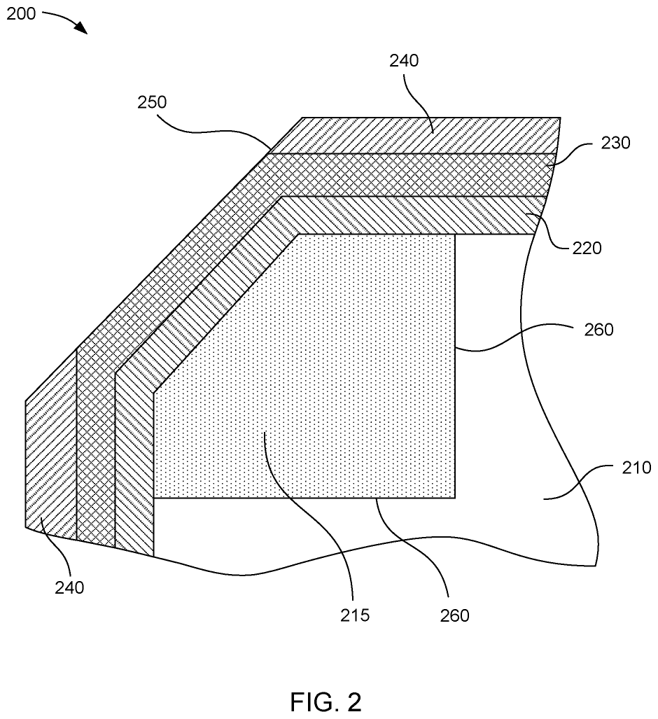

FIG. 2 shows an example cover 200 for an electronic device with a light metal substrate 210. Example covers 200 may include an edge, corner, or a sidewall of a cover. The light metal substrate 210 can be milled, stamped, forged or otherwise altered to create feature 260 designed to accept the light metal substrate 210 being joined with an insert molding plastic part 215. The insert molding plastic part 215 and the light metal substrate 210 are covered with a protective treatment layer 220. The protective treatment layer 220 may be a micro-arc oxidation layer or a passivation layer. The protective treatment layer 220 can be covered with a transparent primer coating 230. The transparent primer coating 230 may be a transparent paint coating 240. The transparent primer coating 230 can be covered with a paint coating 240. The paint coating may be composed of multiple layers include a base coat and a clear top coat. The paint coating 240 can be milled to create a milled edge 250 along a surface of the insert molding plastic part 115. The milled edge 250 cuts through the paint coating 240 to expose the transparent primer coating 230.

The milled edge may be parallel to a surface of the insert molding plastic part 115. The light metal substrate 110 may be milled or otherwise altered along to remove material along a 90° angled edge of the light metal substrate 110. The removed material may be replaced by the insert molding plastic part 115 that has a sloped surface at about a 45° angle compared to two surfaces of the light metal substrate 110. It should be appreciated that any surface, edge, or corner can be cut away from the light metal substrate 110 at any angle and the insert molding plastic part 115 can form any shape or angle. Depending on the shape and design of a cover for an electronic device, the cover may have many different edges. Any of these edges can be shaped or chamfered depending on the desired final appearance of the cover. The resulting milled edges of the present technology may be multi colored such that one milled edge of the cover may be a different color than another milled edge of the cover. The color can come from the transparent primer coating or the insert molding plastic part.

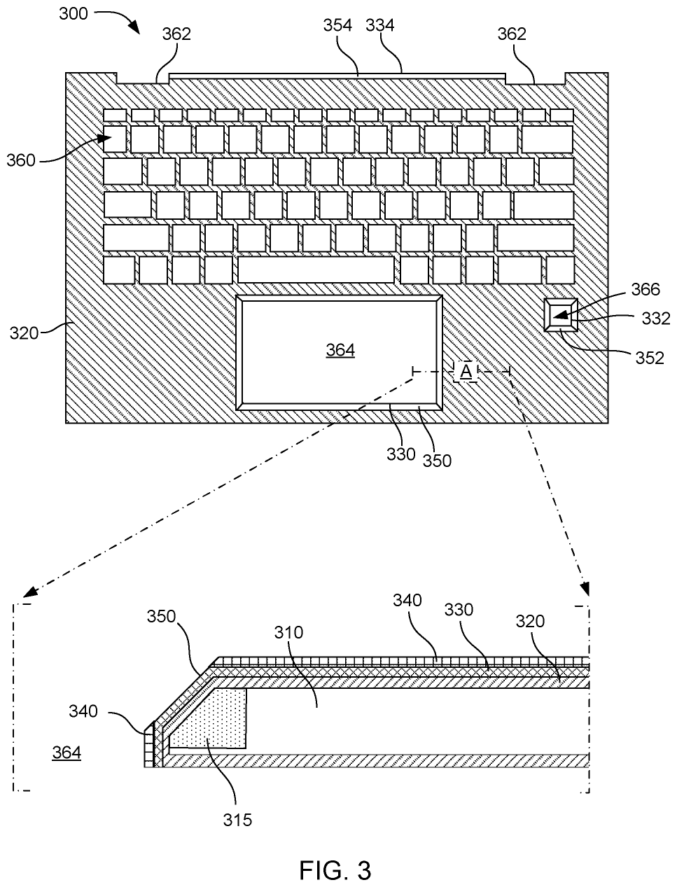

FIG. 3 shows another example cover 300 for an electronic device. This example is a top cover for the keyboard portion of a laptop (sometimes referred to as a “laptop cover C”). The cover includes key openings 360 for the keyboard buttons (not shown) to be positioned therethrough, hinge recesses 362 to receive a hinge (not shown), a track pad opening 364 to receive a track pad (not shown), and a fingerprint scanner opening 366 to receive a fingerprint scanner (not shown). These are merely examples of structures that may be present, and are illustrative of many of a number of other structural components used with this type of top cover. The cover can be mostly made up of a light metal substrate 310 joined with an insert molding plastic part 315. The light metal substrate 310 and the insert molding plastic part 315 are covered with a protective treatment layer 320 that may be deposited using PVD or NCVM. The protective treatment layer can be covered with a transparent primer coating 330. The transparent primer coating 330 can be covered with a paint coating 340. The is paint coating 340 can be milled to remove a portion of the paint coating 340 to form a milled edge 350 and expose a portion of the transparent primer coating 330. The light metal substrate 310 is not directly visible in this example because it is covered by the insert molding plastic part 315. In this example, milled edges have been formed at three different locations: a track pad milled edge 330 surrounding the track pad opening, a fingerprint scanner milled edge 332 surrounding the fingerprint scanner opening, and a rear milled edge 334 along the rear edge of the cover near the hinge. Each of these milled edges expose a transparent primer coating. Pigments or dyes in the insert molding plastic part 115 may be used to introduce a color over the milled edge. For example, the track pad milled edge 330, the fingerprint scanner milled edge 332, and the rear milled edge 334 may each be different colors from one another or may be the same color. Alternatively, the transparent primer coating 330 may be transparent such that the insert molding plastic part 315 can be visible and protected.

To show the various materials in this example more clearly, a partial cross-sectional view is shown along plane “A” designated further by the dashed and dotted lines/arrows. This cross-sectional view shows the milled edge 340 bordering the track pad opening 364. The chamfer cuts through the paint coating 340. As shown in the figure, in this example the milled edge includes a sloping face that slopes downward toward the track pad opening. When the cover is assembled with other components to make a complete laptop, this chamfered edge can provide a more comfortable edge around the track pad compared to a sharp 90° edge. Similarly, the milled edge around the fingerprint scanner can slop downward toward the fingerprint scanner in some examples.

As used herein, “cover” refers to the exterior shell of an electronic device that includes or is in the form of an enclosure, and a portion thereof (or the structure thereof) includes a light metal substrate. In other words, the cover can be adapted to contain the internal electronic components of the electronic device. The cover can be an integral part of the electronic device. The term “cover” is not meant to refer to the type of removable protective cases that are often purchased separately for an electronic device (especially smartphones and tablets) and placed around the exterior of the electronic device. Covers as described herein can be used on a variety of electronic devices. For example, a laptop, a desktop, a keyboard, a mouse, a printer, a smartphone, a tablet, a monitor, a television, a speaker, a game console, a video player, an audio player, or a combination thereof. In various examples, the light metal substrate for these covers can be formed by molding, casting, machining, bending, working, stamping, or another process. In one example, a light metal substrate can be milled from a single block of metal. In other examples, the cover can be made from multiple panels. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). Covers can also be made for smartphones and tablet computers with a single metal piece or multiple metal panels.

As used herein, a layer that is referred to as being “on” a lower layer can be directly applied to the lower layer, or an intervening layer or multiple intervening layers can be located between the layer and the lower layer. Generally, the covers described herein can include a light metal substrate and a protective coating can be applied on the light metal substrate. Accordingly, a layer that is “on” a lower layer can be located further from the light metal substrate. However, in some examples there may be other intervening layers such as a micro-arc oxidation layer or passivation layer underneath the protective layer. Furthermore, the paint coating itself may include multiple layers, such as a base layer, a topcoat layer, and any other intervening layers. In some examples, the protective coating and any other layers may be applied to an exterior surface of the light metal substrate. Thus, a “higher” layer applied “on” a “lower” layer may be located farther from the light metal substrate and closer to a viewer viewing the cover from the outside. In further examples, the protective coating can be applied to all surfaces of the light metal substrate.

It is noted that when discussing covers for electronic devices, the electronic devices themselves, or methods of making covers for electronic devices, such discussions can be considered applicable to one another whether or not they are explicitly discussed in the context of that example. Thus, for example, when discussing the metals used in the light metal substrate in the context of one of the example covers, such disclosure is also relevant to and directly supported in the context of the electronic devices and/or methods, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

### Electronic Devices

A variety of electronic devices can be made with the covers described herein. In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, track pads, fingerprint scanners, cameras, and so on. Accordingly, the covers described herein can include openings for these components. Other electronic components may be designed to be completely enclosed, such as motherboards, batteries, sim cards, wireless transceivers, memory storage drives, and so on. Additionally, in some examples a cover can be made up of two or more cover sections, and the cover sections can be assembled together with the electronic components to enclose the electronic components. As used herein, the term “cover” can refer to an individual cover section or panel, or collectively to the cover sections or panels that can be assembled together with electronic components to make the complete electronic device.

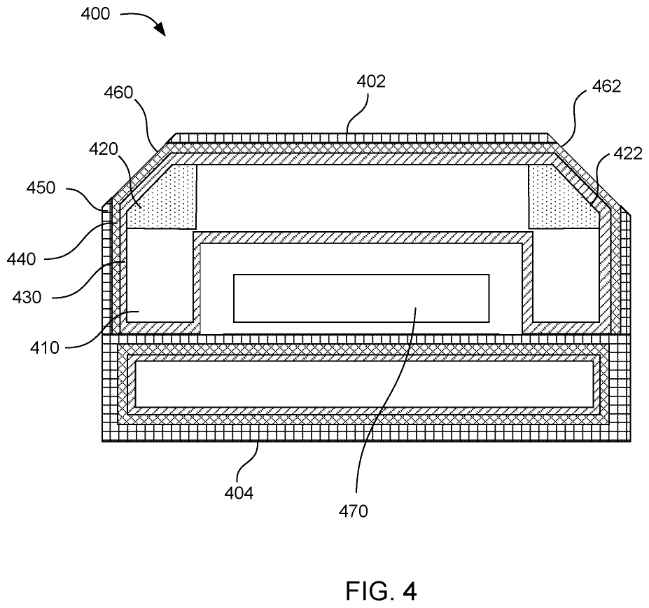

FIG. 4 shows a cross-sectional schematic view of an example electronic device 400 in accordance with examples of the present disclosure. This example includes a top cover 402 and a bottom cover 404 enclosing an electronic component 470. The top cover includes a light metal substrate 410 joined with insert molding plastic parts 420, 422. The light metal substrate 410 and the insert molding plastic parts 420, 422 are covered with a protective treatment layer 430 which may be deposited using PVD or NCVM. The protective treatment layer 430 can be covered with a transparent primer coating 440. The transparent primer coating 440 can be covered with a paint coating 450. The paint coating 450 can be milled to create milled edges 460, 462 to expose the transparent primer coating 440.

In further examples, the electronic device can be a laptop, a desktop, a keyboard, a mouse, a printer, a smartphone, a tablet, a monitor, a television, a speaker, a game console, a video player, an audio player, or a variety of other types of electronic devices. In certain examples, the chamfered edge or edges can be located in decorative locations on the cover. Some examples include chamfered edges around track pads, around fingerprint scanners, around an edge of a logo, and so on. In further detail, there may be outer periphery of the light metal substrate that can be similarly chamfered.

### Methods of Making Covers for Electronic Devices

In some examples, the covers described herein can be made by first forming the light metal substrate. This can be accomplished using a variety of processes, including molding, insert molding, forging, casting, machining, stamping, bending, working, and so on. The light metal substrate can be made from a variety of metals. In one example, the light metal substrate CNC milled, stamped, or forged into a shape with a feature to be joined with an insert molding plastic part. In certain examples, the light metal substrate can include aluminum, magnesium, lithium, niobium, titanium, zinc, or an alloy thereof. As mentioned above, in some examples the light metal substrate can be a single piece while in other examples the light metal substrate can include multiple pieces that each make up a portion of the cover. Additionally, in some examples the light metal substrate can be a composite made up of multiple metals combined, such as having layers of multiple different metals or panels or other portions of the light metal substrate being different metals.

A first protective treatment layer can be applied to the light metal substrate and the insert molding plastic part. In some examples, the protective coating can be applied to any surface of the light metal substrate and/or the insert molding plastic part, including fully or partially covering a single surface, fully or partially covering multiple surfaces, or fully or partially covering the light metal substrate or the insert molding plastic part as a whole. The first protective coating can be applied by any suitable application method. In one example, the first protective coating can be deposited using PVD or NCVM. Before the first protective coating is applied, a second protective coating can be applied to the light metal substrate and/or the insert molding plastic part. The second protective coating can be a micro-arc oxidation layer or a passivation layer.

A transparent primer coating can be applied to the surface of the first protective coating. In one example, the transparent primer coating can be a paint coating that is transparent. A paint coating may be applied to the transparent primer coating. The paint coating may have any number of layers. For example, the paint coating may include a base coat and a clear top coat. The paint coating can be milled to create milled edges that cut through the paint coating and expose the transparent primer coating.

In various examples, milled edges can be referred to as chamfered edges and can be formed at any edge or combination of edges on the cover. The milled edge can vary in depth. The term “depth” of milled edges refers to the amount of the edge that can be cut away by the milled process. The depth of the chamfer can be stated in terms of the distance from the original edge of the cover to the edge of the sloped surface created by the chamfering. In various examples, the chamfer can be from about 0.1 mm to about 1 cm deep. In other examples, the chamfer can be from about 0.2 mm to about 5 mm deep. As stated above, in some examples the chamfer can be symmetrical so that the same amount of material is removed on both faces of the cover that meet at the chamfered edge. In a symmetrical chamfering of a 90° edge, the new sloped surface created by the chamfering at about a 45° angle with respect to the original faces of the cover. However, in other examples, the chamfer can be asymmetrical so that the angle of the sloped surface is different with respect to each of the original faces of the cover. The examples of the depth of the chamfer described above can refer to either side of the chamfer in the case of an asymmetrical chamfer.

The milled edge can be formed using any suitable process that can remove material at the edge of the cover and produce a sloped surface in place of the original edge. In some examples, the chamfer can be formed using a CNC machine such as a milling machine, a router, a laser engraver, a laser cutter, a water jet cutter, a sander, a file, or other methods.

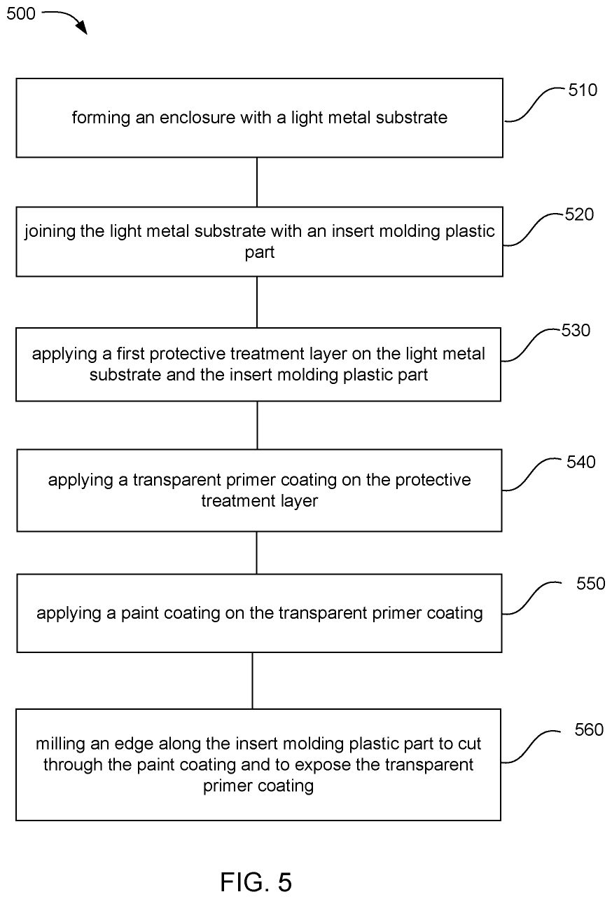

FIG. 5 is a flowchart illustrating an example method 500 of making a cover for an electronic device. The method includes forming 510 an enclosure including a light metal, joining 520 the light metal substrate with an insert molding plastic part, and applying 530 a first protective treatment layer on the light metal substrate and the insert molding plastic part. The method further includes applying 540 a transparent primer coating on the protective treatment layer, and applying 550 a paint coating on the transparent primer coating. The method further includes milling 560 an edge along the insert molding plastic part to cut through the paint coating and to expose the transparent primer coating.

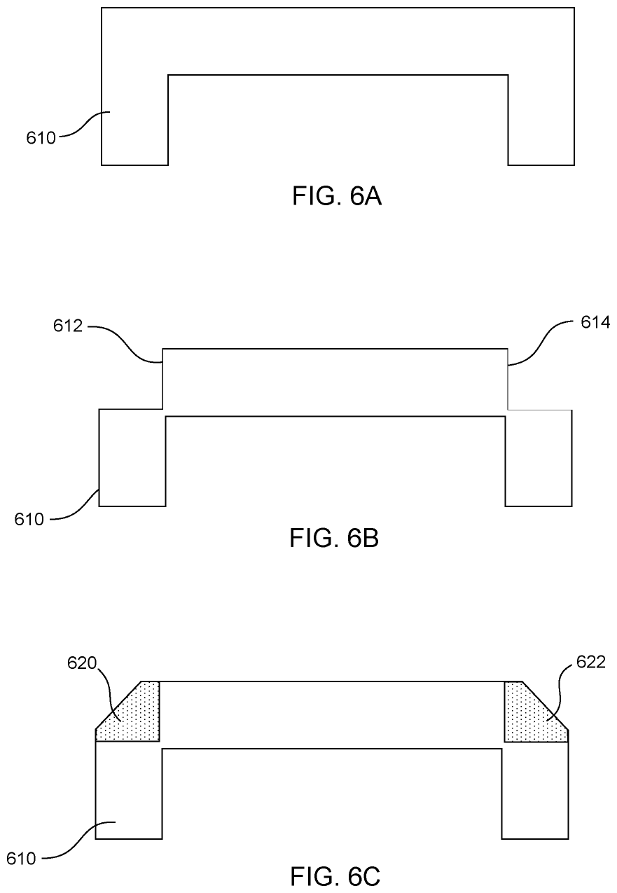

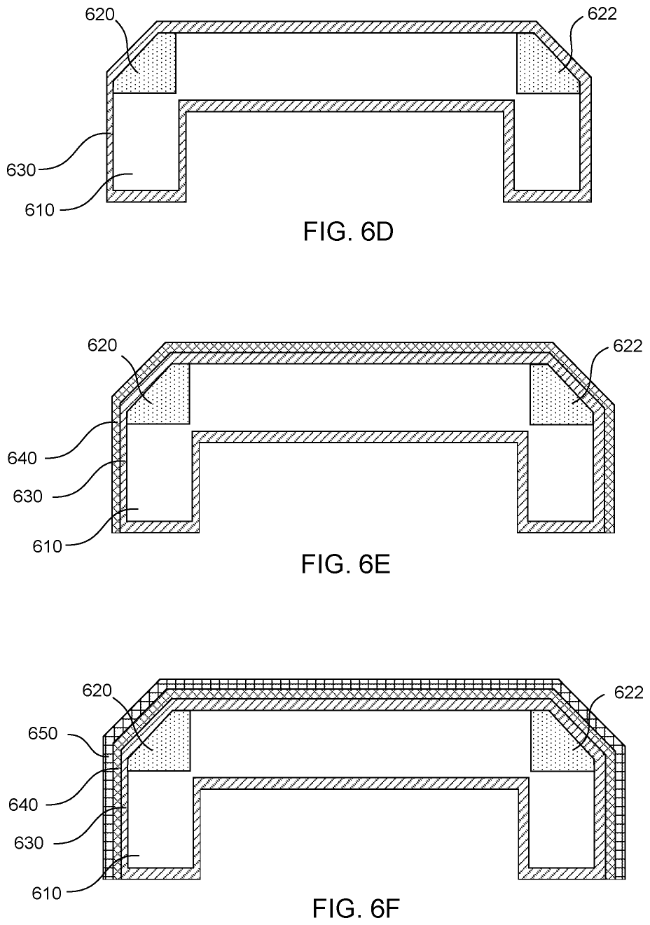

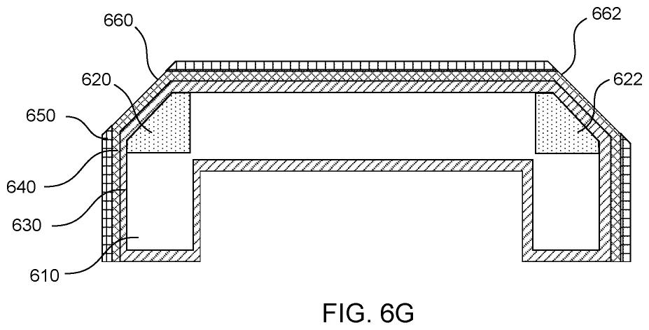

FIGS. 6A-6G show cross-sectional views illustrating another example method of making a cover for an electronic device. In FIG. 6A, a light metal substrate 610 is formed. In FIG. 6B, the light metal substrate 610 can be milled, stamped, forged, or otherwise altered to create features 612, and 614. In FIG. 6C, the light metal substrate 610 can be joined with insert molding plastic parts 620, 622 at the features 612, 614. In FIG. 6D, the light metal substrate 610 and the insert molding plastic parts 620, 622 are coated with a protective treatment layer 630. The protective treatment layer 630 can be deposited using PVD or NCVM. In FIG. 6E, the protective treatment layer 630 can be covered with a transparent primer coating 640. In FIG. 6F, the transparent primer coating 640 can be coated with a paint coating 650. In FIG. 6G, the paint coating 650 can be milled to cut through the paint coating 650, expose a portion of the transparent primer coating 640 and create milled edges 660, 662.

### Light Metal Substrates for Electronic Device Covers

The light metal substrate can be made from a single metal, a metallic alloy, a combination of sections made from multiple metals, or a combination of metal and other materials. In certain examples, the light metal substrate can include aluminum, magnesium, lithium, niobium, titanium, zinc, or an alloy thereof. In further particular examples, the light metal substrate can include aluminum, an aluminum alloy, magnesium, or a magnesium alloy. Non-limiting examples of elements that can be included in aluminum or magnesium alloys can include aluminum, magnesium, titanium, lithium, niobium, zinc, bismuth, copper, cadmium, iron, thorium, strontium, zirconium, manganese, nickel, lead, silver, chromium, silicon, tin, gadolinium, yttrium, calcium, antimony, cerium, lanthanum, or others.

In some examples, the light metal substrate can include an aluminum magnesium alloys made up of about 0.5% to about 13% magnesium by weight and 87% to 99.5% aluminum by weight. Examples of specific aluminum magnesium alloys can include 1050, 1060, 1199, 2014, 2024, 2219, 3004, 4041, 5005, 5010, 5019, 5024, 5026, 5050, 5052, 5056, 5059, 5083, 5086, 5154, 5182, 5252, 5254, 5356, 5454, 5456, 5457, 5557, 5652, 5657, 5754, 6005, 6005A, 6060, 6061, 6063, 6066, 6070, 6082, 6105, 6162, 6262 ,6351, 6463, 7005, 7022, 7068, 7072, 7075 ,7079, 7116, 7129, and 7178.

In further examples, the light metal substrate can include magnesium metal, a magnesium alloy that can be about 99 wt % or more magnesium by weight, or a magnesium alloy that is from about 50 wt % to about 99 wt % magnesium by weight. In a particular example, the light metal substrate can include an alloy including magnesium and aluminum. Examples of magnesium-aluminum alloys can include alloys made up of from about 91% to about 99% magnesium by weight and from about 1% to about 9% aluminum by weight, and alloys made up of about 0.5% to about 13% magnesium by weight and 87% to 99.5% aluminum by weight. Specific examples of magnesium-aluminum alloys can include AZ63, AZ81, AZ91, AM50, AM60, AZ31, AZ61, AZ80, AE44, AJ62A, ALZ391, AMCa602, LZ91, and Magnox.

The light metal substrate can be shaped to fit any type of electronic device, including the specific types of electronic devices described herein. In some examples, the light metal substrate can have any thickness suitable for a particular type of electronic device. The thickness of the metal in the light metal substrate can be selected to provide a desired level of strength and weight for the cover of the electronic device. In some examples, the light metal substrate can have a thickness from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

### First Protective Coatings for Electronic Device Covers

In one example, a protective coating can be applied to the light metal substrate and can be a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt % to about 15 wt % electrolytic compound(s), e.g., alkali metal silicates, alkali metal hydroxide, alkali metal fluorides, alkali metal phosphates, alkali metal aluminates, the like, or a combination thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be about 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, niobium, magnesium, zinc, and/or alloys thereof, for example. The oxidation can extend below the surface to form thick layers, as thick as 30 μm or more. In some examples the oxide layer can have a thickness from about 1 μm to about 25 μm, from about 1 μm to about 22 μm, or from about 2 μm to about 20 μm. Thickness can likewise be from about 2 μm to about 15 μm, from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In some examples, the light metal substrate can include a micro-arc oxidation layer on one side, or on both sides.

In an alternative example, the protective coating is an opaque passivation layer. The passivation layer may refer to a layer or coating over the light metal substrate. Passivation may refer to the use of a light coat of a protective material, such as metal oxide, to create a shell against corrosion. Chemicals may be applied to the surface of the light metal substrate to induce the passivation layer. For example, the chemicals may include at least one of molybdates, vanadates, phosphates, chromates, stannates and manganese salts. The passivation layer may have a thickness of 1-5 μm.

### PVD and NCVM Coatings for Electronic Device Covers

In some examples, a PVD or NCVM protective coating is applied to to the light metal substrate and the insert molding plastic part. The PVD or NCVM protective coating may be applied over the micro-arc oxidation or passivation layer. Physical vapor deposition or PVD may refer to a variety of vacuum deposition methods which can be used to produce thin films and coatings. PVD is characterized by a process in which the material goes from a condensed phase to is a vapor phase and then back to a thin film condensed phase. The most common PVD processes are sputtering and evaporation. PVD is used in the manufacture of items which require thin films for mechanical, optical, chemical or electronic functions. Non-conductive vacuum metalizing or NCVM may refer to the product surface layer of physical vapor deposition of a metal or metal compound film. The PVD or NCVM coating may be composed of titanium, chromium, nickel, zinc, zirconium, manganese, copper, aluminum, tin, molybdenum, tantalum, tungsten, hafnium, gold, vanadium, silver, platinum, graphite, and alloy combinations thereof. The PVD or NCVM protective coating may be 30-100 nm thick.

### Paint Coatings

The paint coating may include a transparent primer coating as well as other paint coatings. The paint coatings may include one, two, three or four layers or any other number of layers. The paint coating may include a primer coat, a base coat, and/or a top coat. The paint coating may be applied using any number of techniques including spray painting or inkjet painting. The paint may be composed of a variety of materials. In one example, a primer coat can include a polyester, a polyurethane, or a copolymer thereof. In one example, a base coat can include a polyester, a polyurethane, or a copolymer thereof. In one example, a top coat can include a polyurethane, a polyacrylic or polyacrylate, a urethane, an epoxy, or a copolymer thereof. The paint coatings can be any number of colors and can be transparent, semi-transparent, or opaque.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics or other opaque particles, whether or not such particulates impart color. Thus, though the present description primarily exemplifies the use of pigment colorants, the term “pigment” can be used more generally to describe pigment colorants and other pigments such as organometallics, ferrites, ceramics, etc. In one specific example, however, the pigment is a pigment colorant.

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm etc.

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

### EXAMPLE

An example cover for an electronic device is made as follows:
1) A light metal substrate is made by molding from magnesium alloy in the form of a laptop cover with a “C” shape and/or as a keyboard surface with openings therein for keys, a track pad, and/or a fingerprint pad.
2) The light metal substrate is subjected to CNC milling to form a feature.
3) The light metal substrate is joined to an insert molding plastic part at the feature.
4) The light metal substrate is subjected to micro-arc oxidation to form a protective coating on the light metal substrate and the insert molding plastic part.
5) The micro-arc oxidation layer is subjected to PVD to form a protective coating.
6) The PVD protective coating is subjected to spray painting a transparent primer coating.
7) The transparent primer coating is subjected to spray painting a paint coating.
8) A laser engraving machine is used to cut a first chamfer along the edges of the opening for the track pad. A second chamfer is cut along the edges of the opening for the fingerprint scanner. A third chamfer is cut along the rear edge of the light metal substrate (outer periphery). The chamfers are cut at about a 45° angle and have a depth of about 2 mm from the corner of the corner (now chamfered and no longer present) along the edge. The to chamfered edges cut through the paint coating to expose the transparent primer coating.

What is claimed is:

1. A cover for an electronic device comprising:
an enclosure with a light metal substrate joined with an insert molding plastic part;
a protective treatment layer on the light metal substrate and the insert molding plastic part;
a transparent primer coating on the protective treatment layer;
a paint coating on the transparent primer coating; and
a milled edge along the insert molding plastic part, wherein the milled edge cuts through the paint coating to expose the transparent primer coating.

2. The cover of claim 1, wherein the light metal substrate includes aluminum, magnesium, titanium, lithium, niobium, or an alloy thereof.

3. The cover of claim 1, wherein the protective treatment layer is deposited using non-conductive vacuum metalizing or physical vapor deposition.

4. The cover of claim 1, wherein the protective treatment layer includes a metal selected from titanium, chromium, nickel, zinc, zirconium, manganese, copper, aluminum, tin, molybdenum, tantalum, tungsten, hafnium, gold, vanadium, silver, platinum, graphite, a combination thereof, or an alloy thereof.

5. The cover of claim 1, further comprising a second protective treatment layer positioned between the protective treatment layer and the light metal substrate, wherein the second protective treatment layer is a micro-arc oxidation layer or a passivation layer.

6. The cover of claim 1, wherein the milled edge is a chamfered edge formed by computer numerical control or laser engraving.

7. The cover of claim 1, wherein the first protective treatment layer has an average thickness from about 10 nm to about 100 nm.

8. The cover of claim 1, wherein the light metal substrate and the insert molding plastic part having an opening therethrough.

9. An electronic device comprising:
an electronic component; and
a cover enclosing the electronic component, the cover comprising:
an enclosure with a light metal substrate joined with an insert molding plastic part;
a protective treatment layer on the light metal substrate and the insert molding plastic part;
a transparent primer coating on the protective treatment layer;
a paint coating on the transparent primer coating; and
a milled edge along the insert molding plastic part, wherein the milled edge cuts through the paint coating to expose the transparent primer coating.

10. The electronic device of claim 9, wherein the electronic device is a laptop, a desktop computer, a keyboard, a mouse, a smartphone, a tablet, monitor, a television, a speaker, a game console, a video player, an audio player, or a combination thereof.

11. The electronic device of claim 9, wherein the milled edge is located at an edge of a touchpad, an edge of a fingerprint scanner, or an edge of a logo.

12. The electronic device of claim 9, wherein the light metal enclosure includes a metal selected from aluminum, magnesium, titanium, lithium, niobium, or an alloy thereof.

13. A method of making a cover for an electronic device comprising:
forming an enclosure with a light metal substrate;
joining the light metal substrate with an insert molding plastic part;
applying a first protective treatment layer on the light metal substrate and the insert molding plastic part;
applying a transparent primer coating on the protective treatment layer;
applying a paint coating on the transparent primer coating; and
milling an edge along the insert molding plastic part to cut through the paint coating and to expose the transparent primer coating.

14. The method of claim 13, wherein the protective treatment layer is deposited using non-conductive vacuum metalizing or physical vapor deposition.

15. The method of claim 13, further comprising applying a second is protective treatment layer positioned between the protective treatment layer and the light metal substrate, wherein the second protective treatment layer is a micro-arc oxidation layer or a passivation layer.
